(19) United States
(12) Patent Application Publication
(10) Pub. No.: US 2025/0359280 A1
(43) Pub. Date: Nov. 20, 2025

(54) BOTTOM-UP METAL GATE FOR STACKED DEVICE STRUCTURE

(71) Applicant: Taiwan Semiconductor Manufacturing Company, Ltd., Hsin-Chu (TW)

(72) Inventors: Kai-Chieh Yang, Hsinchu (TW); Chun-Yu Liu, New Taipei City (TW); Wei-Yen Woon, Taoyuan City (TW); Ku-Feng Yang, Hsinchu County (TW); Szuya Liao, Hsinchu (TW)

(21) Appl. No.: 19/281,220

(22) Filed: Jul. 25, 2025

Related U.S. Application Data
(63) Continuation of application No. 18/600,394, filed on Mar. 8, 2024.
(60) Provisional application No. 63/594,117, filed on Oct. 30, 2023.

(51) Int. Cl. H10D 64/66; H01L 21/288; H10D 30/43; H10D 30/67; H10D 62/10; H10D 64/01; H10D 84/83

(52) U.S. Cl. CPC H10D 64/667; H01L 21/288; H10D 30/43; H10D 30/6735; H10D 30/6757; H10D 62/121; H10D 64/017; H10D 84/83

(57) ABSTRACT

Semiconductor structures and method of forming the same are provided. A method according to the present disclosure includes providing an intermediate structure that includes an opening, conformally depositing a metal liner over the opening, depositing a dummy fill material over the metal liner, recessing the dummy fill material such that a portion of the metal liner is exposed, removing the exposed portion of the metal liner, removing the recessed dummy fill material, and after the removing of the recessed dummy fill material, depositing a metal fill layer over the opening.

### PRIORITY DATA

This application is a continuation of U.S. Non-Provisional application Ser. No. 18/600,394, filed Mar. 8, 2024, which claims priority to U.S. Provisional Patent Application Ser. No. 63/594,117, filed Oct. 30, 2023, each of which is herein incorporated by reference in its entirety for all purposes.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Stacked transistor structures can provide further density reduction for advanced integrated circuit (IC) technology nodes (particularly as they advance to 3 nm (N3) and below), especially when the stacked transistor structures include multi-gate devices, such as fin-like field effect transistors (FinFETs), gate-all-around (GAA) transistors including nanowires and/or nanosheets, other types of multi-gate devices, etc. Stacked transistor structures vertically stack transistors. For example, a transistor stack can include a first transistor (e.g., a top transistor) disposed over a second transistor (e.g., a bottom transistor). The transistor stack can provide a complementary field effect transistor (CFET) when the first transistor and the second transistor are of opposite conductivity type (i.e., an n-type transistor and a p-type transistor).

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method 100 for depositing metal fill layer in an opening, according to one or more aspects of the present disclosure.

FIGS. 2-10 illustrate fragmentary cross-sectional views of a work-in-progress (WIP) structure undergoing various fabrication processes in the method of FIG. 1, according to one or more aspects of the present disclosure.

FIG. 11 illustrates a flow chart of a method 100 for depositing metal fill layer in an opening, according to one or more aspects of the present disclosure.

FIGS. 12-20 illustrate fragmentary cross-sectional views of a WIP structure undergoing various fabrication processes in the method of FIG. 10, according to one or more aspects of the present disclosure.

FIGS. 21-28 illustrate representative fragmentary cross-sectional views of different WIP structures undergoing various fabrication processes in method of FIG. 1 or FIG. 11, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

Gate structures for multi-gate devices and stacked multi-gat devices may be formed using gate-last processes. In an example gate-last process, a dummy gate stack or a placeholder gate stack is first formed over a channel region of an active region of the multi-gate device and stacked multi-gat device. A gate spacer is formed along sidewalls the dummy gate stack. After source/drain features are formed, the dummy gate stack is removed and the remaining gate spacer defines a gate trench. For GAA transistors or stacked multi-gate devices, channel members are released from sacrificial semiconductor layers by selective etching. The functional gate structure, with a gate dielectric layer, at least one work function layer and a gate fill layer, is then deposited in the gate trench. Because the gate fill layer is deposited in a high-aspect-ratio opening, gate fill layer may prematurely merge to block line of sight, resulting in voids and seams in the gate structure. These voids and seams not only increase resistance and may lead to defects when the gate structure is etched back for further process steps.

The present disclosure provides a bottom-up deposition method to deposit a metal fill layer in a high-aspect-ratio opening. The high-aspect-ratio opening may include a partially-filled gate trench for a multi-gate transistor or a stacked multi-gate transistor or even a contact opening for a back-end-of-line (BEOL) structure. Methods of the present disclosure may selectively deposit a metal liner or a metal catalyst over a lower portion of the high-aspect-ratio opening. Then a metal fill layer is deposited over the metal liner or the metal catalyst using electroless plating in a bottom-top manner.

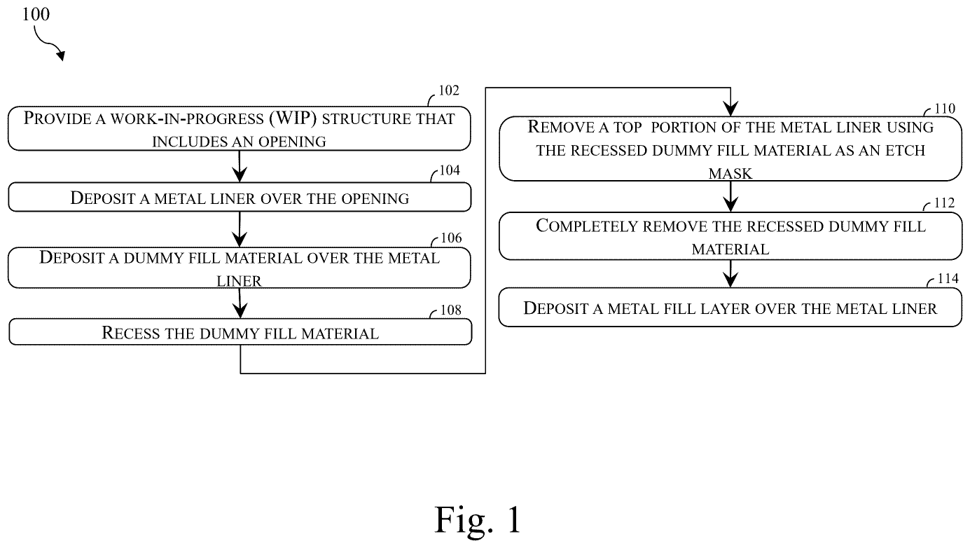

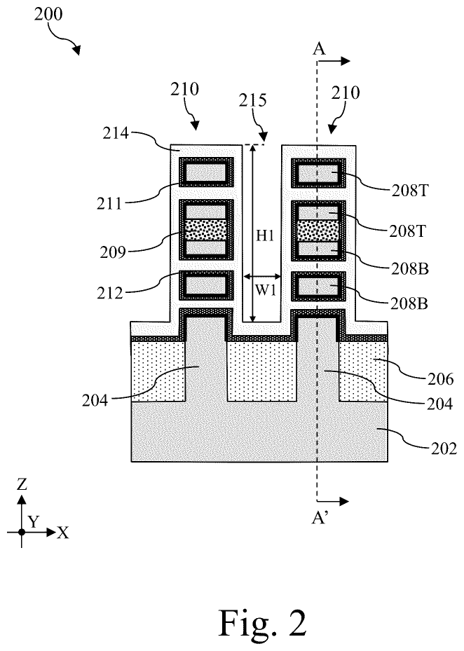

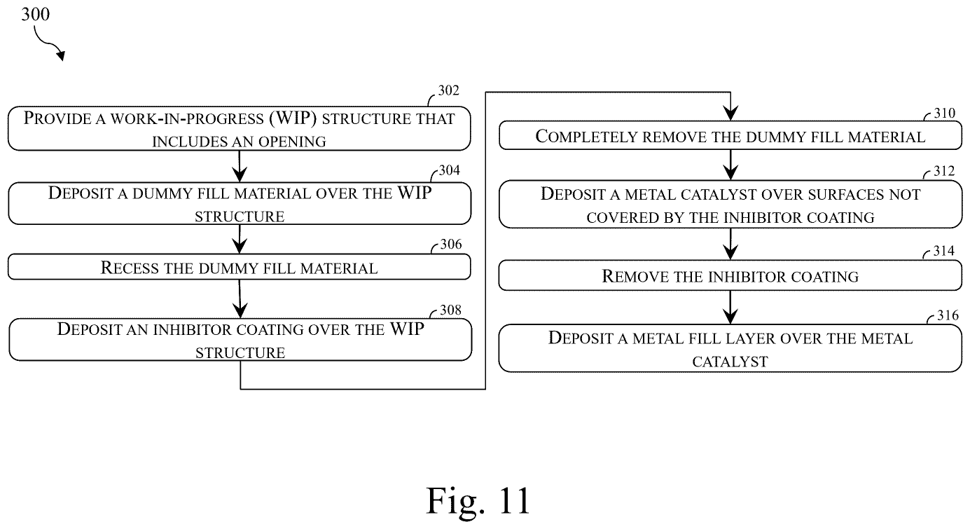

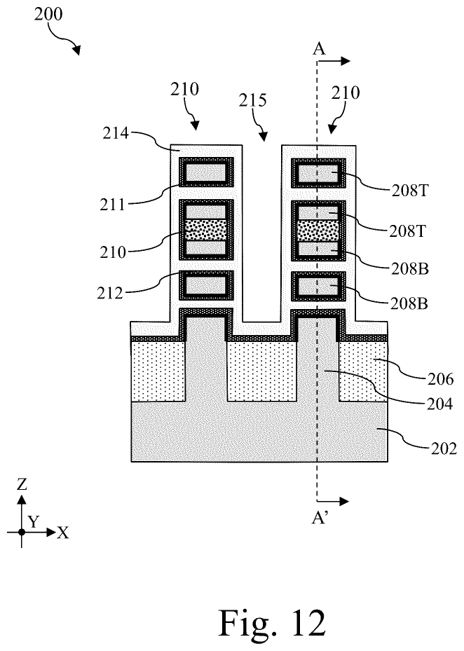

The various aspects of the present disclosure will now be described in more detail with reference to the figures. In that regard, FIGS. 1 and 11 are flowcharts illustrating method 100 and method 300 for depositing a metal fill layer in a high-aspect-ratio opening according to various aspects of the present disclosure. Methods 100 and 300 are merely examples and are not intended to limit the present disclosure to what is explicitly illustrated in methods 100 and 300. Additional steps may be provided before, during and after method 100 and 300, and some steps described can be replaced, eliminated, or moved around for additional embodiments of the method. Not all steps are described herein in detail for reasons of simplicity. Method 100 is described below in conjunction with FIGS. 2-10, which are fragmentary cross-sectional views of a work-in-progress (WIP) structure 200 at different stages of fabrication according to embodiments of method 100. Method 300 is described below in conjunction with FIGS. 12-19, which are fragmentary cross-sectional views of a WIP structure 200 at different stages of fabrication according to embodiments of method 300. When undergoing various processes of the present disclosure, the WIP structure 200 may also be referred to as a workpiece or an intermediate structure. Because the WIP structure 200 will be fabricated into a semiconductor device 200 upon conclusion of the fabrication processes, the WIP structure 200 may be referred to as the semiconductor device 200 as the context requires. Additionally, throughout the present application and across different embodiments, like reference numerals denote like features with similar structures and compositions, unless otherwise excepted. Source/drain region(s) may refer to a source or a drain, individually or collectively dependent upon the context.

Method 100 deposits a metal fill layer over a high-aspect-ratio opening in a bottom-up manner by selectively depositing a metal liner over a bottom portion of the high-aspect-ratio opening and then depositing the metal fill layer over the metal liner.

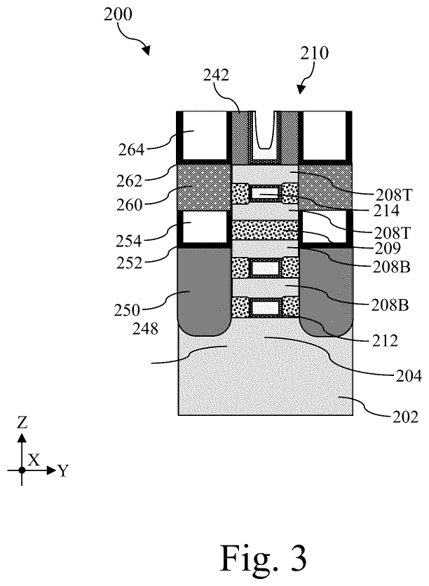

Referring to FIGS. 1, 2 and 3, method 100 includes a block 102 where a work-in-progress (WIP) structure 200 that includes an opening 215 is provided. In some embodiments represented in FIG. 2, the WIP structure 200 is intended for fabrication of a stacked multi-gate transistor. FIG. 3 illustrates a fragmentary cross-sectional view across line A-A′ in FIG. 2. The WIP structure 200 includes a substrate 202 and fin-shaped structures 210 disposed over the substrate 202. In one embodiment, the substrate 202 may be a silicon (Si) substrate. In some other embodiments, the substrate 202 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 202 may also include an insulating layer, such as a silicon oxide layer, to have a silicon-on-insulator (SOI) structure. The fin-shaped structures 210 may be patterned from the substrate 202 and a semiconductor stack disposed over the substrate 202. Each of the fin-shaped structures 210 includes a base fin 204, bottom channel members 208B over the base fin 204, a middle insulation layer 209 over the bottom channel member 208B, and top channel members 208T. The base fin 204 rises continuously from the substrate 202 and shares the same composition with the substrate 202. Each of the base fins 204 is surrounded by an isolation feature 206 to be insulated laterally from one another. In some embodiments, the bottom channel members 208B and the top channel members 208T may include silicon (Si). The middle insulation layer 209 is vertically sandwiched between a topmost one of the bottom channel members 208B and a bottommost one of the top channel members 208T. Please note that, for illustration purposes, figures of the present disclosure illustrate only two bottom channel members 208B and two top channel members 208T. Additional bottom channel members 208B or top channel members 208T are fully envisioned by the present disclosure.

The isolation feature 206 may also be referred to as a shallow trench isolation (STI) feature 206. In an example process, a dielectric material for the isolation feature 206 is deposited over the WIP structure 200, including the fin-shaped structure 210, using CVD, subatmospheric CVD (SACVD), flowable CVD (FCVD), spin-on coating, and/or other suitable process. Then the deposited dielectric material is planarized and recessed to form the isolation feature 206. The dielectric material for the isolation feature may include silicon oxide, silicon oxynitride, fluorine-doped silicate glass (FSG), a low-k dielectric, combinations thereof, and/or other suitable materials. As shown in FIG. 2, after the recessing, the base fins 204 rise above the isolation feature 206. The middle insulation layer 209 may include silicon oxide, silicon nitride, or a combination thereof. When viewed along the X direction as shown in FIG. 3, the isolation feature 206 may not be visible.

Reference is made to FIG. 3. The bottom channel members 208B extend lengthwise along the Y direction between two bottom source/drain features 250 and the top channel members 208T extend lengthwise along the Y direction between two top source/drain features 260. The bottom source/drain features 250 may be formed using an epitaxial process, such as vapor phase epitaxy (VPE), ultra-high-vacuum chemical vapor deposition (UHV-CVD), molecular beam epitaxy (MBE), and/or other suitable processes. The epitaxial growth process may use gaseous and/or liquid precursors, which interact with the composition of base fin 204, bottom channel members 208B and top channel members 208T. The epitaxial growth of the bottom source/drain features 250 may take place from both the top surface of the base fin 204 and the exposed sidewalls of the bottom channel members 208B. The epitaxial growth of the top source/drain features 260 may take place from the exposed sidewalls of the top channel members 208T. In the embodiments represented in the figures, the bottom source/drain features 250 are p-type and may include silicon germanium (SiGe) doped with a p-type dopant, such as boron (B). The top source/drain features 260 are n-type and may include silicon (Si) doped with an n-type dopant, such as a phosphorus (P) or arsenic (As). Each of the bottom channel members 208B and the top channel members 208T includes a width along a channel width direction (X-direction in FIG. 2) and a height along the Z direction. In the depicted embodiments, the width is greater than the height and each of the bottom channel members 208B and the top channel members 208T may be referred to as a nanosheet or a nanostructure.

Referring still to FIG. 3, the top source/drain features 260 are at least spaced apart from the bottom source/drain features 250 by a bottom contact etch stop layer (CESL) 252 and a bottom interlayer dielectric (ILD) layer 254. The bottom CESL 252 may include silicon nitride, silicon oxynitride, and/or other materials known in the art. The bottom ILD layer 254 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. and may be formed by CVD, ALD, plasma-enhanced chemical vapor deposition (PECVD) process and/or other suitable deposition or oxidation processes. In some embodiments, the bottom CESL 252 is first conformally deposited on the WIP structure 200 using CVD, ALD, PECVD and the bottom ILD layer 254 is deposited over the bottom CESL 252 by spin-on coating, FCVD, CVD, or other suitable deposition technique. In some embodiments, after formation of the bottom ILD layer 254, the WIP structure 200 may be annealed to improve integrity of the bottom ILD layer 254. As shown in FIG. 3, after the deposition of the bottom CESL 252 and the bottom ILD layer 254, the bottom CESL 252 and the bottom ILD layer 254 are etched back to exposed sidewalls of the top channel members 208T. Similarly, a top contact etch stop layer (CESL) 262 and a top interlayer dielectric (ILD) layer 264 are deposited over the top source/drain features 260. The top CESL 262 may share a similar composition and a similar formation process with the bottom CESL 252. The top ILD layer 264 may share a similar composition and a similar formation process with the bottom ILD layer 252.

In the depicted embodiments, the WIP structure 200 in FIGS. 2 and 3 is formed using a gate-last process where a dummy gate stack (or a replacement gate stack) is formed over a channel region of the fin-shaped structure 210. After deposition of a gate spacer 242 along sidewalls of the fin-shaped structure 210, the source/drain trenches that are now filled with the bottom source/drain features 250 and the top source/drain features 260 are formed by anisotropic etching. After removal of the dummy gate stack and release of the bottom channel members 208B and the top channel members 208T, the gate spacer 242 and inner spacer features 248 define a gate trench now filled with the interfacial layer 211, the high-k dielectric layer 212, and the metal nitride layer 214. The gate spacer 242 and the inner spacer features 248 may include silicon oxycarbonitride, silicon carbonitride, or silicon nitride.

In the WIP structure 200 in FIG. 2, an interfacial layer 211 is formed over exposed surfaces of the base fins 204, bottom channel members 208B and top channel members 208T. A high-k dielectric layer 212 is disposed over the interfacial layer 211. In some embodiments, the interfacial layer 211 includes silicon oxide or hafnium silicate and may be formed in a pre-clean process. An example pre-clean process may include use of RCA SC-1 (ammonia, hydrogen peroxide and water) and/or RCA SC-2 (hydrochloric acid, hydrogen peroxide and water). The high-k dielectric layer 212 is then deposited over the interfacial layer 211 using atomic layer deposition (ALD), CVD, and/or other suitable methods. As used and described herein, high-k dielectric materials include dielectric materials having a high dielectric constant, for example, greater than that of thermal silicon oxide (˜3.9). In one embodiment, the high-k dielectric layer 212 may include hafnium oxide. Alternatively, the high-k dielectric layer 212 may include other high-K dielectrics, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. As shown in FIG. 2, because the middle insulation layer 209 covers the top surface of the topmost bottom channel members 208B and the bottom surface of the bottommost channel members 208T, the interfacial layer 211 is spaced apart from the top surface of the topmost bottom channel members 208B and the bottom surface of the bottommost channel members 208T. Because the pre-clean process does not oxidize the isolation feature 206, the interfacial layer 211 is not formed over surfaces of the isolation feature 206. The high-k dielectric layer 212 is deposited on the isolation feature 206, wraps over the base fins 204, and wraps around at least one bottom channel member 208B and at least one top channel member 208T. In the embodiments represented in FIG. 2, the high-k dielectric layer 212 wraps around the topmost bottom channel member 208B, the middle insulation layer 209 and the bottommost top channel members 208T as a whole. The high-k dielectric layer 212 does not extend between the topmost bottom channel member 208B and the middle insulation layer 209 or between the bottommost top channel member 208T and the middle insulation layer 209.

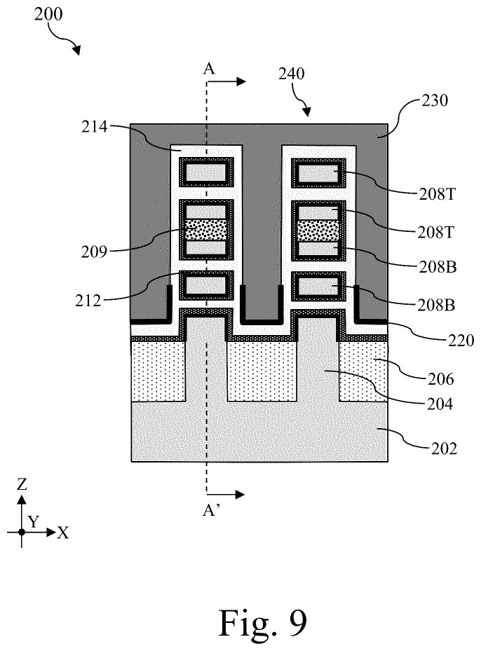

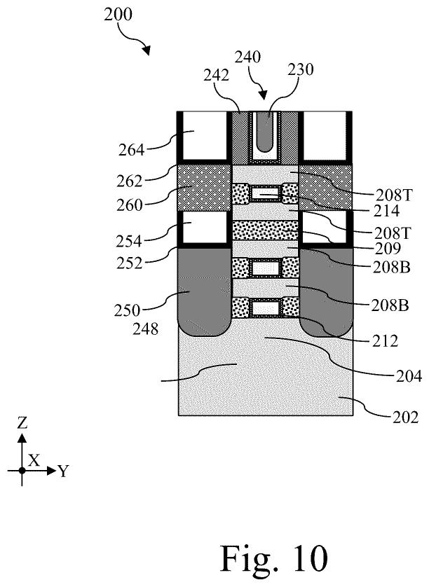

As part of a gate structure 240 (shown in FIGS. 9 and 10), a metal nitride layer 214 is deposited over the WIP structure 200. As shown in FIG. 2, the metal nitride layer 214 is deposited over the high-k dielectric layer 212 to wrap over the bottom channel members 208B and top channel members 208T. In the depicted embodiments, the metal nitride layer 214 completely fills the space between the bottom channel members 208B and the space between the top channel members 208T. The metal nitride layer 214 is also disposed over the high-k dielectric layer 212 over the isolation feature 206. In some embodiments, the metal nitride layer 214 may include titanium nitride and may serve as a work function metal layer, such as a p-type work function metal layer. The fin-shaped structures 210 and the metal nitride layer 214 define an opening 215 between two fin-shaped structures 210. The opening 215 includes a first width (W1) along the X direction and a first height (H1) along the Z direction. In some embodiments, a ratio of the first height (H1) to the first width (W1) defines a first aspect ratio between 3 and 10. The opening 215 is considered a high-aspect-ratio opening.

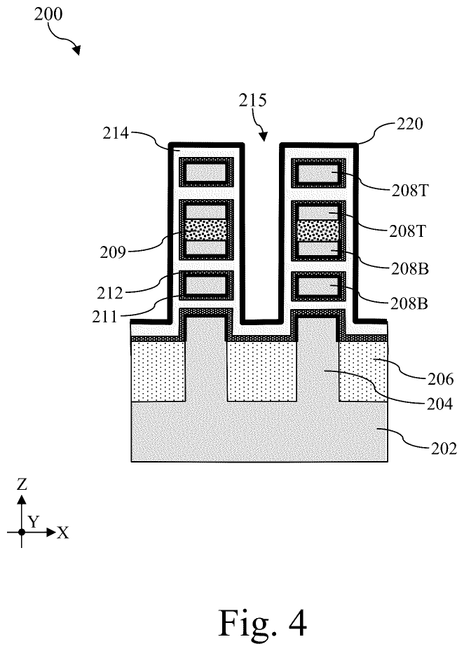

Referring to FIGS. 1 and 4, method 100 includes a block 104 where a metal liner 220 is deposited over the opening 215. In some embodiments, the metal liner 220 may include ruthenium (Ru), cobalt (Co), molybdenum (Mo), palladium (Pd), platinum (Pt), gold (Au), or iridium (Ir). At block 104, the metal liner 220 may be conformally deposited over the metal nitride layer 214 using atomic layer deposition (ALD). In some instances, the metal liner 220 is deposited to have a thickness between about 5 Å and about 20 Å.

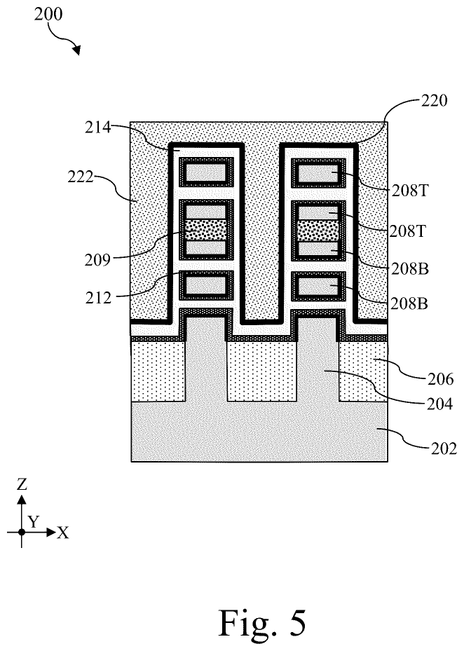

Referring to FIGS. 1 and 5, method 100 includes a block 106 where a dummy fill material 222 is deposited over the metal liner 220. In some embodiments, the dummy fill material 222 may include a bottom antireflective coating (BARC) layer. In some instances, the BARC layer may include silicon-containing polymers, carbon- containing polymers, or spin-on carbon (SOC). The dummy fill material 222 may be deposited using flowable CVD (FCVD) or spin-on coating. In the depicted embodiments, a top surface of the dummy fill material 222 is higher than a top surface of the metal nitride layer 214 to completely fill the opening 215.

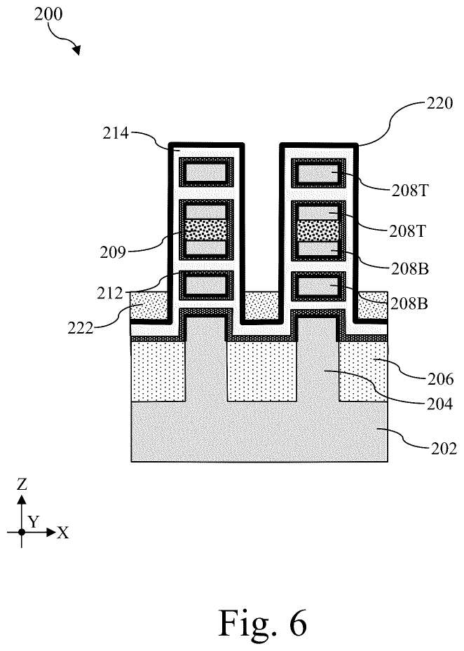

Referring to FIGS. 1 and 6, method 100 includes a block 108 where the dummy fill material 222 is recessed. At block 108, the dummy fill material 222 is anisotropically etched back or recessed to have a reduced height. As shown in FIGS. 5 and 6, the height of the dummy fill material 222 is reduced from completely covering the opening 215 to covering a bottom portion of the opening 215. In some embodiments, the anisotropic etch back at block 108 may include use of a dry etch process that uses nitrogen plasma, hydrogen plasma, argon (Ar), or a combination thereof. As shown in FIG. 6, after the dummy fill material is etched back, a top portion of the metal liner 220 is exposed while a bottom portion of the metal liner 220 remains covered by the etched-back dummy fill material 222.

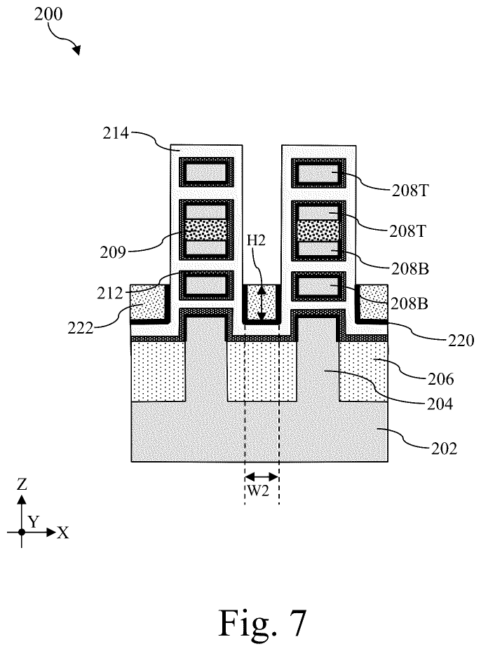

Referring to FIGS. 1 and 7, method 100 includes a block 110 where the top portion of the metal liner 220 is removed using the recessed dummy fill material 222 as an etch mask. In some embodiments, a selective wet etch process may be used to selective remove the exposed top portion of the metal liner 220 that is not covered by the recessed dummy fill material 222. The selective wet etch at block 110 may include use of hydrochloric acid (HCl), nitric acid (HNO₃), hydrogen peroxide (H₂O₂), or a mixture thereof. As shown in the FIG. 7, after the selective removal of the top portion of the metal liner 220, the recessed dummy fill material 222 that covers the bottom portion of the metal liner 220 may have a second width (W2) along the X direction and a second height (H2) along the Y direction. An aspect ratio of the recessed dummy fill material 222 is the ratio of the second height H2 to the second width W2 and is between 1 and 2.

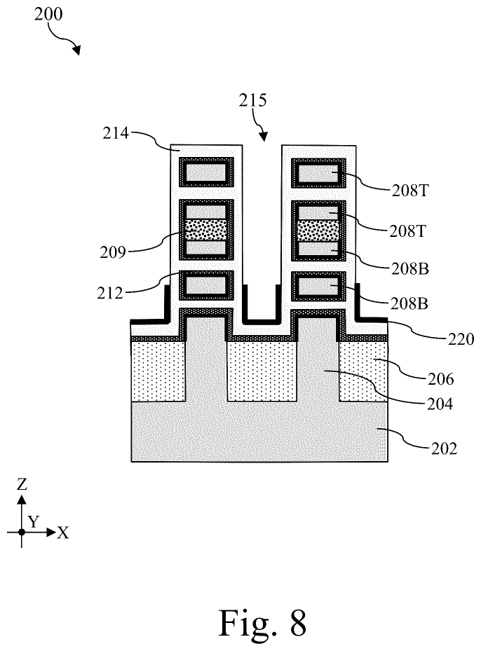

Referring to FIGS. 1 and 8, method 100 includes a block 112 where the dummy fill material 222 is completely removed. At block 112, the dummy fill material 222 is removed by a dry etch process that includes use of nitrogen plasma, hydrogen plasma, argon (Ar), or a combination thereof. The dry etch process at block 112 etches the metal liner 220 at a slower rate and the bottom portion of the metal liner 220 remains after the dummy fill material 222 is completely removed from the WIP structure 200, as shown in FIG. 8.

Referring to FIGS. 1 and 9-10, method 100 includes a block 114 a metal fill layer 230 is deposited over the metal liner 220. In some embodiments, the metal fill layer 230 is deposited using electroless plating at block 114. In an example process, a pre-clean treatment that includes both dry clean and wet clean is performed to remove surface oxidation, organic debris and metallic debris. Then the WIP structure 200 is immersed into a plating solution containing metallic precursor, an organic chelating agent, a reducing agent, a stabilizer, a PH adjusting agent, or a wetting agent. The reducing agent reacts with the metallic precursor, thereby depositing the metal of the metallic precursor to form the metal fill layer 230. The deposition of the metal fill layer 230 starts from the bottom portion of the metal liner 220 and takes place in a bottom-up manner. In some implementations, the metal fill layer 230 includes nickel (Ni), copper (Cu), silver (Ag), gold (Au), palladium (Pd), ruthenium (Ru), platinum (Pt), or iridium (Ir) or an alloy such as nickel phosphorus (NiP) or cobalt nickel phosphorus (CoNiP). As shown in FIG. 9, after the metal fill layer 230 is deposited, a top surface of the metal fill layer 230 is higher than a top surface of the metal nitride layer 214. In some embodiments, a post anneal process may be performed after the deposition of the metal fill layer 230 to promote regrowth and reflow of the metal fill layer 230. It has been observed that the metal fill layer 230 formed using method 100 tends to be seam-free and provide low resistance. As shown in FIGS. 9 and 10, with the deposition of the metal fill layer 230, a gate structure 240 is substantially formed. The gate structure 240 includes the metal fill layer 230, the metal nitride layer 214, the bottom portion of the metal liner 220, the high-k dielectric layer 212, and the interfacial layer 211. The gate structure 240 wraps completely around at least one of the bottom channel members 208B and at least one of the top channel members 208T.

Method 300 deposits a metal fill layer over a high-aspect-ratio opening in a bottom-up manner by selectively depositing a metal catalyst over a bottom portion of the high-aspect-ratio opening and then depositing the metal fill layer over the metal catalyst.

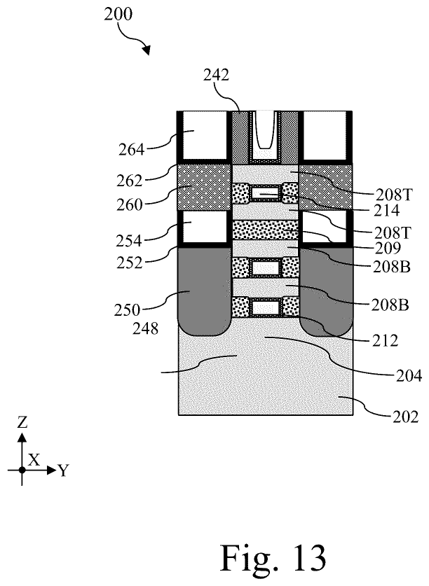

Referring to FIGS. 11, 12 and 13, method 300 includes a block 302 where a work-in-progress (WIP) structure 200 that includes an opening 215 is provided. WIP structure shown in FIGS. 12-13 are similar to those illustrated in FIGS. 2-3. For the sake of brevity, a detailed description of the WIP structure 200 in FIGS. 12 and 13 is omitted.

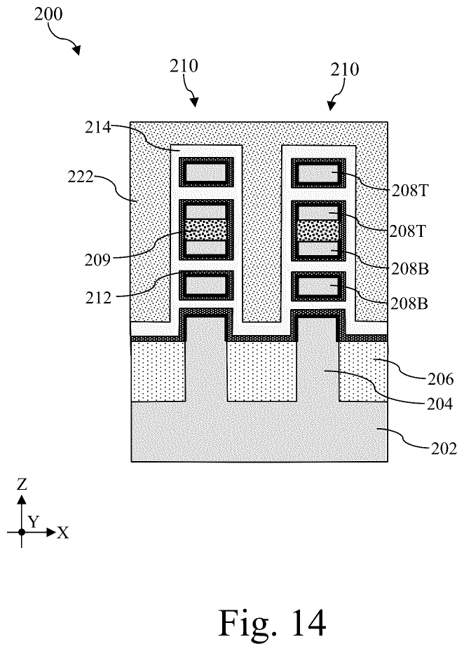

Referring to FIGS. 11 and 14, method 300 includes a block 304 where a dummy fill material 222 is deposited over the opening 215. In some embodiments, the dummy fill material 222 may include a bottom antireflective coating (BARC) layer or silicon oxycarbide (SiOC). In some instances, the BARC layer may include silicon-containing polymers, carbon-containing polymers, or spin-on carbon (SOC). The dummy fill material 222 may be deposited using flowable CVD (FCVD) or spin-on coating. In the depicted embodiments, a top surface of the dummy fill material 222 is higher than a top surface of the metal nitride layer 214 to completely fill the opening 215.

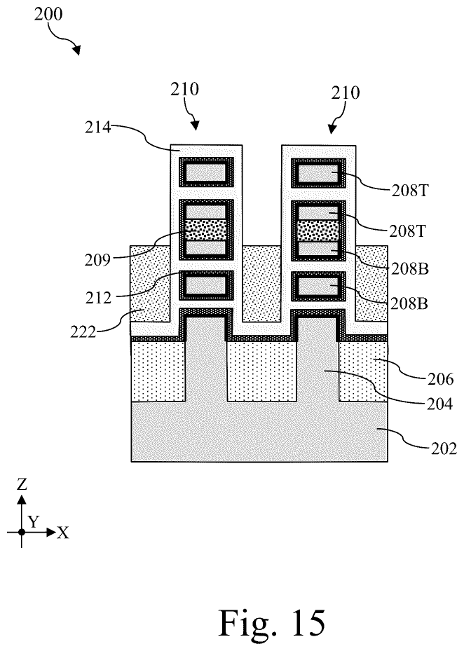

Referring to FIGS. 11 and 15, method 300 includes a block 306 where the dummy fill material 222 is recessed. At block 306, the dummy fill material 222 is anisotropically etched back or recessed to have a reduced height. As shown in FIGS. 14 and 15, the height of the dummy fill material 222 is reduced from completely covering the opening 215 to covering a bottom portion of the opening 215. In some embodiments, the anisotropic etch back at block 306 may include use of a dry etch process that uses nitrogen plasma, hydrogen plasma, argon (Ar), or a combination thereof. As shown in FIG. 15, after the dummy fill material 222 is etched back, a top portion of the metal nitride layer 214 is exposed while a bottom portion of the metal nitride layer 214 remains covered by the etched-back dummy fill material 222.

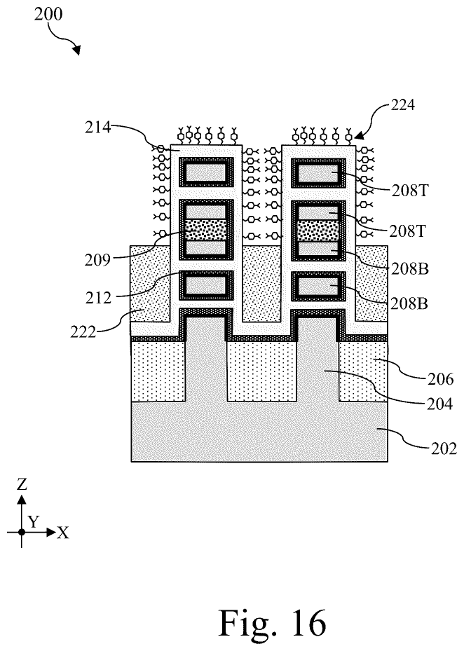

Referring to FIGS. 11 and 16, method 300 includes a block 308 where an inhibitor coating 224 is deposited over the exposed portion of the metal nitride layer 214. The inhibitor coating 224 include a small-molecule inhibitor (SMI) or a self-assembled monolayer (SAM). In some embodiments, the inhibitor coating 224 includes a molecule that includes a head group to interact with the metal nitride layer 214 and a bulky tail group to inhibit deposition of material on the metal nitride layer 214. An SMI may include silane, aniline, pyridine, toluidine, phenylenediamine, toluenediamine, naphthylamine, or aminopyridine. An SAM may include chlorosilanes or alkoxysilanes. In some instances, the SAM may include various functional groups. In one embodiment, the inhibitor coating 224 includes silane. Because the bottom portion of the metal nitride layer 214 is covered by the dummy fill material 222, the inhibitor coating 224 is only deposited over the exposed surfaces of the metal nitride layer 214, include a top surface of the metal nitride layer 214.

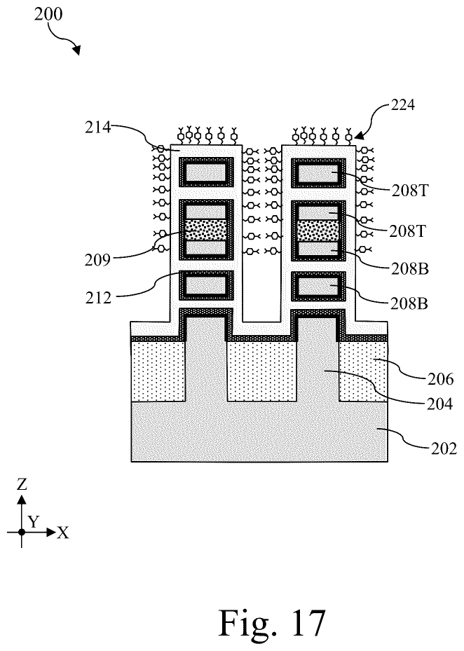

Referring to FIGS. 11 and 17, method 300 includes a block 310 where the dummy fill material 222 is completely removed. After the deposition of the inhibitor coating 224, the dummy fill material 222 is removed by a dry etch process that includes use of nitrogen plasma, hydrogen plasma, argon (Ar), or a combination thereof. The removal of the dummy fill material 222 exposes surfaces of a bottom portion of the metal nitride layer 214. The exposed surfaces of the bottom portion of the metal nitride layer 214 is not protected or covered by the inhibitor coating 224.

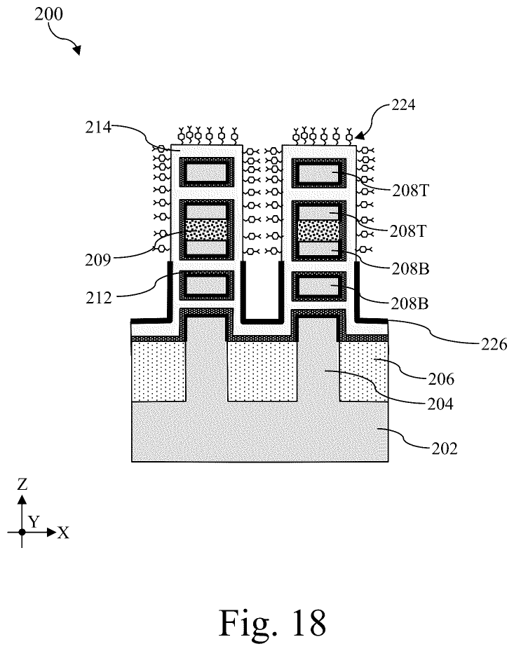

Referring to FIGS. 11 and 18, method 300 includes a block 312 where a metal catalyst 226 is deposited over surfaces not covered by the inhibitor coating 224. In some embodiments, the metal catalyst 226 may include nanoparticles of ruthenium (Ru), palladium (Pd), platinum (Pt), or gold (Au). In one embodiment, the metal catalyst 226 includes nanoparticles of palladium (Pd). In some instances, the nanoparticles of the metal catalyst 226 may be about 1 nm to 2 nm in size. At block 312, the metal catalyst 226 maybe deposited using spin-on coating or dip coating. A coverage density of the metal catalyst 226 on the exposed surface of the metal nitride layer 214 is related to the deposition of the metal fill layer 230 at block 316. In most instances, a greater coverage density is preferred as it leads to a denser and faster deposition of the metal fill layer 230. Operations at block 312 may also be referred to as metal catalyst decoration.

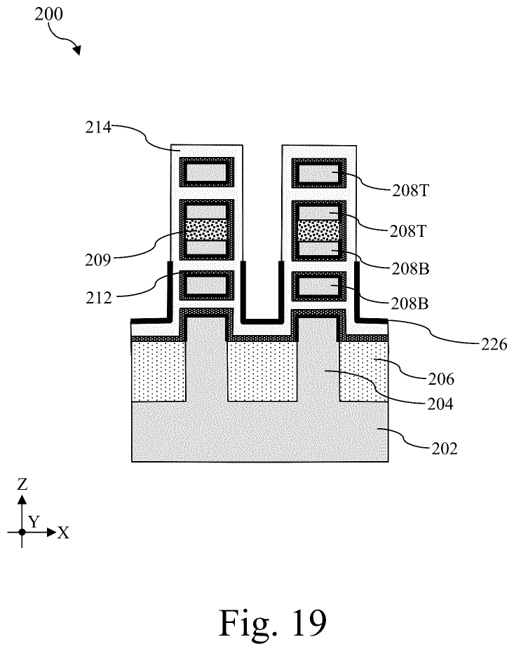

Referring to FIGS. 11 and 19, method 300 includes a block 314 where the inhibitor coating 224 is removed from the WIP structure 200. In some embodiments, the inhibitor coating 224 may be removed by thermal pumping. In an example thermal pumping process, the WIP structure 200 is heated up until the bonding between the inhibitor coating 224 and the metal nitride layer 214 becomes weaker and the inhibitor coating 224 is removed by pumping. At this point, a bottom portion of the metal nitride layer 214 is covered by the metal catalyst 226 and a top portion of the metal nitride layer 214 is exposed.

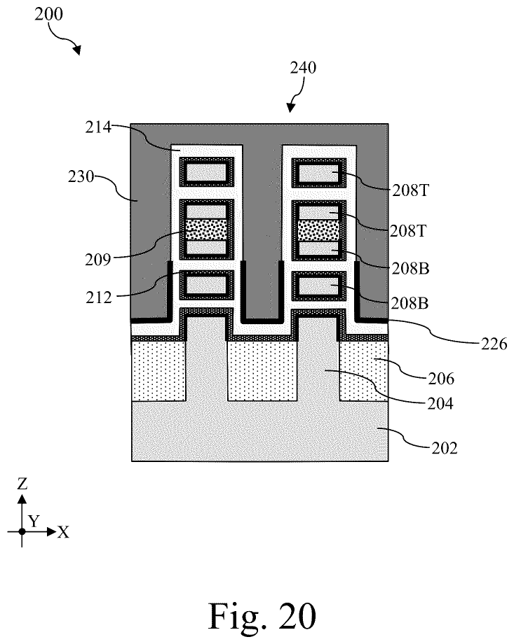

Referring to FIGS. 11 and 20, method 100 includes a block 316 a metal fill layer 230 is deposited over the metal catalyst 226. In some embodiments, the metal fill layer 230 is deposited using electroless plating at block 316. In an example process, a pre-clean treatment that includes both dry clean and wet clean may be performed to remove surface oxidation, organic debris and metallic debris, provided that the pre-clean treatment does not disturb or remove the metal catalyst 226. Then the WIP structure 200 is immersed into a plating solution containing metallic precursor, an organic chelating agent, a reducing agent, a stabilizer, a PH adjusting agent, or a wetting agent. The reducing agent reacts with the metallic precursor, thereby depositing the metal of the metallic precursor to form the metal fill layer 230. The deposition of the metal fill layer 230 starts from the metal catalyst 226 at the bottom portion of the metal nitride layer 214 and takes place in a bottom-up manner in the opening 215. In some implementations, the metal fill layer 230 includes nickel (Ni), copper (Cu), silver (Ag), gold (Au), palladium (Pd), ruthenium (Ru), platinum (Pt), or iridium (Ir) or an alloy such as nickel phosphorus (NiP) or cobalt nickel phosphorus (CoNiP). As shown in FIG. 20, after the metal fill layer 230 is deposited, a top surface of the metal fill layer 230 is higher than a top surface of the metal nitride layer 214. That is, the metal fill layer 230 completely fill the opening 215. In some embodiments, a post anneal process may be performed to increase a density of the metal fill layer 230 or to remove voids in the metal fill layer 230. It has been observed that the metal fill layer 230 formed using method 300 tends to be seam-free and provide low resistance. With the deposition of the metal fill layer 230, a gate structure 240 is substantially formed. The gate structure 240 includes the metal fill layer 230, the metal nitride layer 214, the metal catalyst 226, the high-k dielectric layer 212, and the interfacial layer 211. The gate structure 240 wraps completely around at least one of the bottom channel members 208B and at least one of the top channel members 208T.

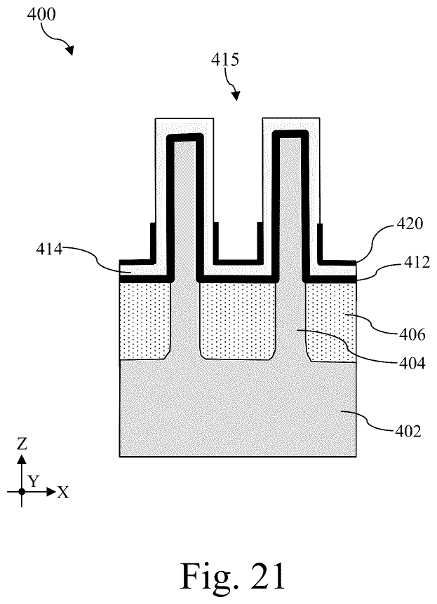

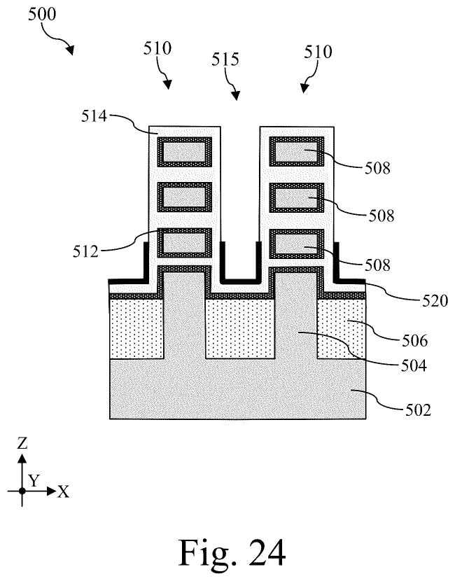

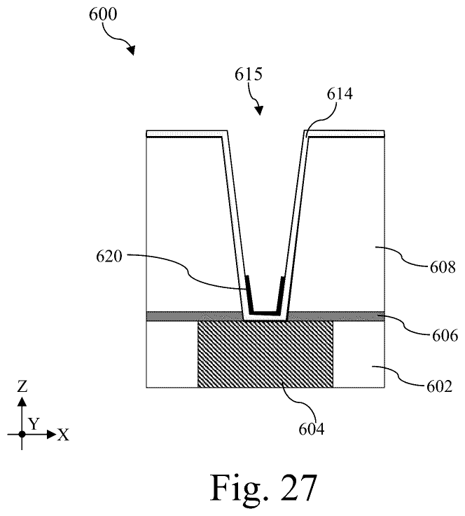

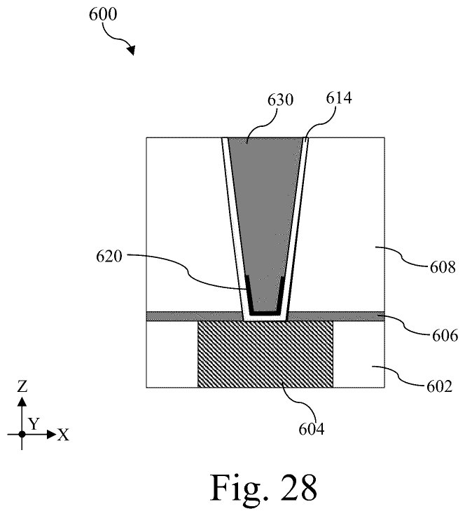

Besides being used in fabrication of stacked multi-gate devices as shown in FIGS. 2-10 and 12-20, methods 100 and 300 may also be used in a fin-type field effect transistor (FinFET) shown in FIGS. 21-23, in a GAA transistor shown in FIGS. 24-26, or in a back-end-of-line (BEOL) contact structure shown in FIGS. 27-28. While not explicitly described herein, it should be immediately apparent to people of ordinary skill in the art that methods of the present disclosure may also be applied to planar devices when deposition of a metal fill layer in a high-aspect-ratio opening is needed.

Reference is first made to FIGS. 21-23, which illustrate a work-in-progress (WIP) structure 400 that is intended for fabrication of FinFET structures. Referring to FIG. 21, the WIP structure 400 includes fins 404 rising from a top surface of a substrate 402. The fins 404 are patterned from a portion of the substrate 402 and are laterally insulated from one another by an isolation feature 406. A gate dielectric layer 412 is deposited over the fins 404 and the isolation feature 406. The gate dielectric layer 412 includes an interfacial layer and a high-k dielectric layer over the interfacial layer. A metal nitride layer 414 is deposited over the gate dielectric layer 412 by ALD. In one embodiment, the substrate 402 may be a silicon (Si) substrate. In some other embodiments, the substrate 402 may include other semiconductors such as germanium (Ge), silicon germanium (SiGe), or a III-V semiconductor material. The substrate 402 may also include an insulating layer, such as a silicon oxide layer, to have a silicon-on-insulator (SOI) structure. The fins 404 rise continuously from the substrate 402 and share the same composition with the substrate 402. The isolation feature 406 may also be referred to as a shallow trench isolation (STI) feature 406. The isolation feature 406 may include silicon oxide, silicon oxynitride, fluorine-doped silicate glass (FSG), a low-k dielectric, combinations thereof, and/or other suitable materials.

In some embodiments, the interfacial layer in the gate dielectric layer 412 includes silicon oxide or hafnium silicate and may be formed in a pre-clean process. The high-k dielectric layer in the gate dielectric layer 412 include hafnium oxide. Alternatively, the high-k dielectric layer may include other high-K dielectrics, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. In some embodiments, the metal nitride layer 414 may include titanium nitride and may serve as a work function metal layer, such as a p-type work function metal layer. The fins 404 and the metal nitride layer 414 define an opening 415 between fins 404 in FIG. 21.

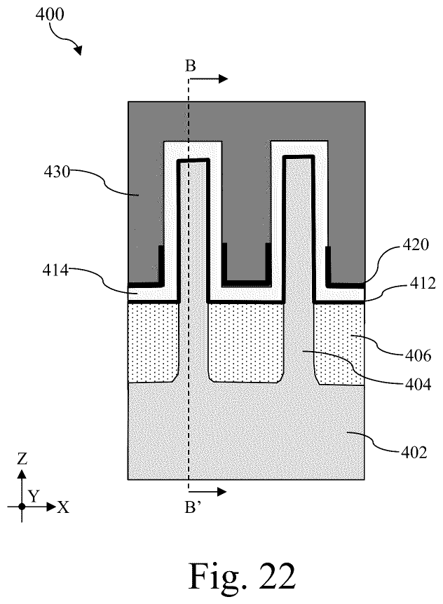

By using either method 100 or method 300, a metal nucleation layer 420 is formed to cover a bottom portion of the metal nitride layer 414. When method 100 is used, the metal nucleation layer 420 may be similar to the metal liner 220. When method 300 is adopted, the metal nucleation layer 420 may be similar to the metal catalyst 226. Like the metal liner 220 or the metal catalyst 226, the metal nucleation layer 420 facilitate bottom-up deposition of a metal fill layer 430 shown in FIG. 22. The metal fill layer 430 may be deposited using techniques described above with respect to operations in block 114. That is, the metal fill layer 430 may be deposited using electroless plating. In some embodiments, the metal fill layer 430 includes nickel (Ni), copper (Cu), silver (Ag), gold (Au), palladium (Pd), ruthenium (Ru), platinum (Pt), or iridium (Ir) or an alloy such as nickel phosphorus (NiP) or cobalt nickel phosphorus (CoNiP).

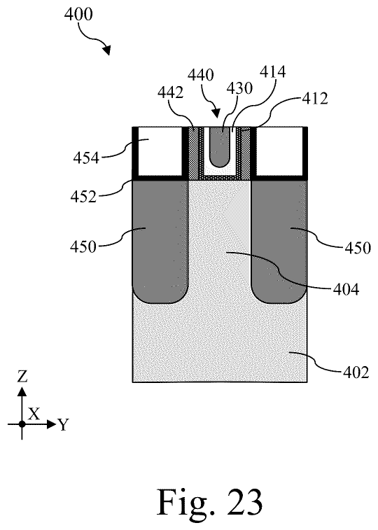

FIG. 23 illustrates a fragmentary cross-sectional view along line B-B′ in FIG. 22. Along the Y direction, the fin 404 extends between two source/drain features 450. The source/drain features 450 may be n-type or p-type. When they are n-type, they may include silicon (Si) and an n-type dopant, such as phosphorus (P) or arsenic (As). When they are p-type, they may include silicon germanium (SiGe) and a p-type dopant, such as boron (B). A gate structure 440 wraps over a channel region of the fin 404. The gate structure 440 includes the metal fill layer 430, the metal nitride layer 214, the metal nucleation layer 420, and the gate dielectric layer 412. Because line B-B's cuts through the fin 404, the metal nucleation layer 420 is not shown in FIG. 23. Sidewalls of a top portion of the gate structure 440 over the fin 404 are lined by a gate spacer 442. A contact etch stop layer (CESL) 452 is deposited over the source/drain features 450 and an interlayer dielectric (ILD) layer 454 is disposed over the CESL 452. A composition of the CESL 452 may be similar to that of the bottom CESL 252. A composition of the ILD layer 454 may be similar to that of the bottom ILD layer 254.

Reference is then made to FIGS. 24-26, which illustrate a work-in-progress (WIP) structure 500 that is intended for fabrication of GAA structures. Referring to FIG. 24, the WIP structure 500 includes a plurality of channel members 508 disposed over a base fin 504. The base fins 504 rise continuously from a top surface of a substrate 502. The base fins 504 are patterned from a portion of the substrate 502 and are insulated from one another by an isolation feature 506. A gate dielectric layer 512 is deposited to wrap around each of the channel members 508 and over a top surface of the isolation feature 506. A base fin 504 and the channel members 508 disposed directly over it may be collectively referred to a fin-shaped structure 510. The gate dielectric layer 512 includes an interfacial layer and a high-k dielectric layer over the interfacial layer. A metal nitride layer 514 is deposited over the gate dielectric layer 512 by ALD. The metal nitride layer 514 is disposed along sidewalls of the channel members 508 and defines an opening 515 disposed between two fin-shaped structures 510. Each of the fin-shaped structures 510 includes a base fin 504 and a vertical stack of channel members 508 disposed directly over the base fin 504.

In one embodiment, the substrate 502 may be a silicon (Si) substrate. In some other embodiments, the substrate 502 may include other semiconductors such as germanium (Ge), silicon germanium (SiGe), or a III-V semiconductor material. The substrate 502 may also include an insulating layer, such as a silicon oxide layer, to have a silicon-on-insulator (SOI) structure. The fin-shaped structures 510 may be patterned from the substrate 502 and a semiconductor stack disposed over the substrate 502. The base fin 504 rises continuously from the substrate 502 and shares the same composition with the substrate 502. The channel members 508 may include silicon (Si). Please note that, for illustration purposes, figures of the present disclosure illustrate three bottom channel members 508. It should be understood that the WIP structure 500 may include fewer or more channel members. The isolation feature 506 may also be referred to as a shallow trench isolation (STI) feature 506. The isolation feature 506 may include silicon oxide, silicon oxynitride, fluorine-doped silicate glass (FSG), a low-k dielectric, combinations thereof, and/or other suitable materials.

The interfacial layer in the gate dielectric layer 512 may include silicon oxide or hafnium silicate and may be formed in a pre-clean process. The high-k dielectric layer in the gate dielectric layer 512 may include hafnium oxide. Alternatively, the high-k dielectric layer may include other high-K dielectrics, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. The metal nitride layer 514 may include titanium nitride and may serve as a work function metal layer, such as a p-type work function metal layer.

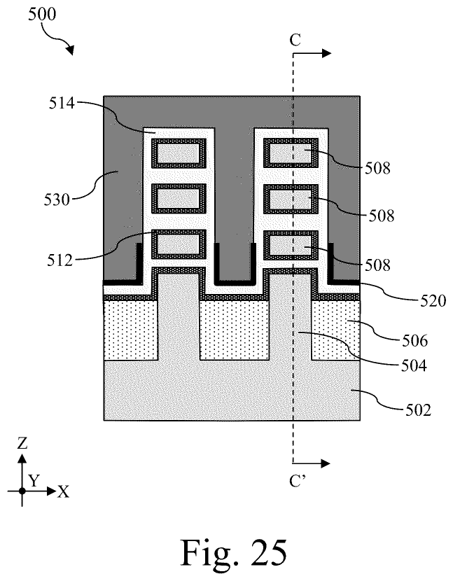

By using either method 100 or method 300, a metal nucleation layer 520 is formed to cover a bottom portion of the metal nitride layer 514. When method 100 is used, the metal nucleation layer 520 may be similar to the metal liner 220. When method 300 is adopted, the metal nucleation layer 520 may be similar to the metal catalyst 226. Like the metal liner 220 or the metal catalyst 226, the metal nucleation layer 520 facilitate bottom-up deposition of a metal fill layer 530 shown in FIG. 25.

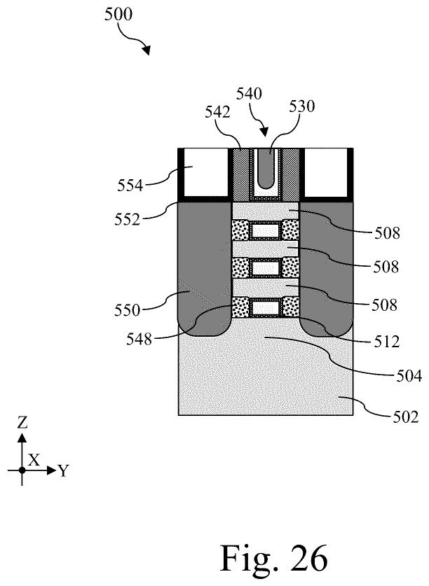

FIG. 26 illustrates a fragmentary cross-sectional view along line C-C′ in FIG. 25. Along the Y direction, the channel members 508 extend between two source/drain features 550. The source/drain features 550 may be n-type or p-type. When they are n-type, they may include silicon (Si) and an n-type dopant, such as phosphorus (P) or arsenic (As). When they are p-type, they may include silicon germanium (SiGe) and a p-type dopant, such as boron (B). A gate structure 540 wraps around each of the channel members 508. The gate structure 540 includes the metal fill layer 530, the metal nitride layer 514, the metal nucleation layer 520, and the gate dielectric layer 512. Because line C-C's cuts through the channel members 508, the metal nucleation layer 520 is not shown in FIG. 26. Sidewalls of a top portion of the gate structure 540 over the channel members 508 are lined by a gate spacer 542. A contact etch stop layer (CESL) 552 is deposited over the source/drain features 550 and an interlayer dielectric (ILD) layer 554 is disposed over the CESL 552. A composition of the CESL 552 may be similar to that of the bottom CESL 252. A composition of the ILD layer 554 may be similar to that of the bottom ILD layer 254.

Finally, reference is now made to FIGS. 27-28, which illustrate a work-in-progress (WIP) structure 600 that is intended for a contact structure. The WIP structure 200 includes a contact feature 604 disposed in a first dielectric layer 602. An etch stop layer (ESL) 606 is disposed over top surfaces of the contact feature 604 and the first dielectric layer 602. A second dielectric layer 608 is disposed over the ESL 606. An opening 615 is formed through the second dielectric layer 608 and the ESL 606. A barrier layer 614 is deposited over the opening 615. In some embodiments, the first dielectric layer 602 and the second dielectric layer 608 may include silicon oxide, silicon oxynitride, fluorine-doped silicate glass (FSG), a low-k dielectric, combinations thereof, and/or other suitable materials. The ESL 606 may include silicon nitride, oxygen-doped silicon carbide, nitrogen-doped silicon carbide, silicon oxynitride, aluminum oxide, or aluminum nitride. The contact feature 604 may include copper (Cu), cobalt (Co), nickel (Ni), ruthenium (Ru), or tungsten (W) and may represent a source/drain contact, a source/drain contact via, a gate contact via, or a metal line. The barrier layer 614 may include titanium nitride (TiN).

By using either method 100 or method 300, a metal nucleation layer 620 is formed to cover a bottom portion of the barrier layer 614 in the opening 615. When method 100 is used, the metal nucleation layer 620 may be similar to the metal liner 220. When method 300 is adopted, the metal nucleation layer 620 may be similar to the metal catalyst 226. Like the metal liner 220 or the metal catalyst 226, the metal nucleation layer 620 facilitate bottom-up deposition of a metal fill layer 630 shown in FIG. 28. After deposition of the metal fill layer 630, a planarization process, such as a chemical mechanical polishing (CMP) process, is performed to provide a planar top surface for the WIP structure 600.

In one exemplary aspect, the present disclosure is directed to a method. The method includes providing an intermediate structure that includes an opening, conformally depositing a metal liner over the opening, depositing a dummy fill material over the metal liner, recessing the dummy fill material such that a portion of the metal liner is exposed, removing the exposed portion of the metal liner, removing the recessed dummy fill material, and after the removing of the recessed dummy fill material, depositing a metal fill layer over the opening.

In some embodiments, the opening is defined between two fin-shaped structures that are covered by a metal nitride layer. In some implementations, the metal nitride layer includes titanium nitride. In some embodiments, each of the two fin-shaped structures includes a plurality of bottom channel members and a plurality of top channel members disposed over the plurality of bottom channel members. In some embodiments, each of the two fin-shaped structures further includes an insulation layer sandwiched between a topmost bottom channel member of the plurality of bottom channel members and a bottommost top channel member of the plurality of top channel members. In some instances, the metal liner includes Ru, Co, Mo, Pd, Pt, Au, or Ir. In some embodiments, the conformally depositing of the metal liner includes use of atomic layer deposition (ALD). In some embodiments, the dummy fill material includes a bottom antireflective coating (BARC) material. In some embodiments, the metal fill layer includes Ni, Cu, Ag, Au, Pd, Ru, Pt, Ir, NiP, or CoNiP. In some implementations, the depositing of the metal fill layer includes use of electroless plating.

In another exemplary aspect, the present disclosure is directed to a method. The method includes providing an intermediate structure that includes an opening, depositing a dummy fill material over the opening, recessing the dummy fill material to expose sidewalls of the opening, selectively depositing an inhibitor layer over the exposed sidewalls of the opening, selectively removing the dummy fill material, after the selectively removing, depositing a metal catalyst over the opening, after the depositing of the metal catalyst, selectively removing the inhibitor layer, and after the removing of the inhibitor layer, depositing a metal fill layer over the metal catalyst in the opening.

In some embodiments, the selectively removing of the inhibitor layer includes use of thermal pumping. In some implementations, the selectively depositing of the inhibitor layer includes use of silane. In some embodiments, the metal catalyst includes Pd. In some embodiments, the depositing of the metal fill layer includes use of electroless plating.

In yet another exemplary aspect, the present disclosure is directed to a semiconductor structure. The semiconductor structure includes a substrate, a first base fin and a second base fin rising from the substrate, an isolation feature disposed over the substrate and between the first base fin and the second base fin, a first plurality of nanostructures over the first base fin, a second plurality of nanostructures over the second base fin, a gate dielectric layer over the first base fin, the first plurality of nanostructures, the second plurality of nanostructures, the second base fin, and the isolation feature, a metal nitride layer over the gate dielectric layer, and a gate fill layer over the metal nitride layer. An upper portion of the gate fill layer is in direct contact with the metal nitride layer and a lower portion of the gate fill layer is spaced apart from the metal nitride layer by a metal liner.

In some embodiments, the metal nitride layer includes titanium nitride. In some implementations, the metal liner includes Ru, Co, Mo, Pd, Pt, Au, or Ir. In some embodiments, the gate fill layer includes Ni, Cu, Ag, Au, Pd, Ru, Pt, Ir, NiP, or CoNiP. In some instances, the metal liner includes Pd.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

1. A semiconductor structure, comprising:
a substrate;
a base fin protruding from the substrate;
an isolation feature disposed over the substrate and extending along a sidewall of the base fin;
channel members disposed over the base fin;
a gate dielectric layer disposed over the base fin and each of the channel members;
a gate fill layer over the gate dielectric layer; and
a metal layer comprising a first portion that partially extends along a sidewall of a bottom portion of the gate fill layer.

2. The semiconductor structure of claim 1, further comprising a metal nitride layer disposed between the gate dielectric layer and the gate fill layer.

3. The semiconductor structure of claim 2, wherein the first portion of the metal layer partially extends along an interface between the bottom portion of the gate fill layer and a bottom portion of the metal nitride layer.

4. The semiconductor structure of claim 1, wherein the metal layer further comprises a second portion that extends over a top surface of the isolation feature.

5. The semiconductor structure of claim 2, wherein a top portion of the metal nitride layer directly interfaces with a top portion of the gate fill layer.

6. The semiconductor structure of claim 1, wherein the channel members comprise a bottom channel member, a top channel member disposed over the bottom channel member, and an insulation layer disposed between the bottom channel member and the top channel member.

7. The semiconductor structure of claim 6, wherein the first portion of the metal layer overlaps a sidewall of the bottom channel member.

8. The semiconductor structure of claim 6, further comprising:
a bottom source/drain feature coupled to the bottom channel member; and
a top source/drain feature coupled to the top channel member, wherein the bottom source/drain feature and the top source/drain feature are of different conductivity types.

9. The semiconductor structure of claim 1, wherein the metal layer comprises a metal catalyst or a metal nucleation layer.

10. A method, comprising:
providing a semiconductor structure comprising:
a base fin protruding from a substrate,
channel members stacked over the base fin,
a gate dielectric layer disposed over the base fin and the channel members, and
a metal nitride layer disposed over the gate dielectric layer;
forming a metal layer over the metal nitride layer; and
forming a gate fill layer over the metal layer, wherein a first portion of the metal layer partially extends along an interface between a bottom portion of the gate fill layer and a bottom portion of the metal nitride layer.

11. The method of claim 10, wherein a top portion of the metal nitride layer directly interfaces with a top portion of the gate fill layer.

12. The method of claim 10, wherein forming the gate fill layer comprises implementing a bottom-up plating process that starts from the metal layer.

13. The method of claim 10, wherein forming the metal layer comprises:
depositing a metal liner over the metal nitride layer,
depositing a dummy fill material over the metal liner,
removing a portion of the dummy fill material to expose a top portion of the metal liner,
removing the exposed top portion of the metal liner such that a remaining portion of the dummy fill material is disposed over a bottom portion of the metal liner, and
removing the remaining portion of dummy fill material from the bottom portion of the metal liner, wherein the bottom portion of the metal liner remains as the metal layer over the metal nitride layer.

14. The method of claim 10, wherein forming the metal layer comprises:
depositing a dummy fill material over the metal nitride layer,
removing a portion of the dummy fill material to expose a top portion of the metal nitride layer,
depositing an inhibitor coating over the exposed top portion of the metal nitride layer,
after depositing the inhibitor coating, removing a remaining portion of the dummy fill material to expose a bottom portion of the metal nitride layer,
depositing a metal catalyst layer over the exposed bottom portion of the metal nitride layer, and
after depositing the metal catalyst layer, removing the inhibitor coating, wherein the metal catalyst layer remains as the metal layer over the metal nitride layer.

15. The method of claim 14, wherein the inhibitor coating comprises a small-molecule inhibitor (SMI) or a self-assembled monolayer (SAM).

16. The method of claim 14, wherein depositing the metal catalyst layer comprises coating the semiconductor structure with metallic nanoparticles.

17. The method of claim 14, wherein removing the inhibitor coating comprises:
heating the semiconductor structure to weaken a bonding between the inhibitor coating and the top portion of the metal nitride layer, and
pumping away the inhibitor coating.

18. A method, comprising:
providing a semiconductor structure comprising:
a first base fin and a second base fin adjacent to the first base fin,
channel members stacked over each of the first base fin and the second base fin,
a gate dielectric layer disposed over the first base fin, the second base fin, and the channel members, and
a metal nitride layer disposed over the gate dielectric layer;
forming a metal layer over a bottom portion the metal nitride layer, wherein a top portion of the metal nitride layer is free of contact with the metal layer; and
forming a gate fill layer over the metal layer and the top portion of the metal nitride layer.

19. The method of claim 18, wherein forming the gate fill layer comprises implementing a bottom-up plating process that starts from the metal layer.

20. The method of claim 18, wherein the metal layer comprises:
sidewall portions each extending along a sidewall of the metal nitride layer, and
a bottom portion coupled between the sidewall portions, wherein the bottom portion extends between the first base fin and the second base fin.
